(19) United States
(12) Patent Application Publication
(10) Pub. No.: US 2026/0201595 A1
(43) Pub. Date: Jul. 16, 2026

(54) METHOD FOR PREPARING EPITAXIAL STRUCTURE AND EPITAXIAL STRUCTURE PREPARED THEREBY

(71) Applicant: Leap Semiconductor Corp., Taoyuan City (TW)

(72) Inventors: Wen-Chung LI, Taoyuan City (TW); Kai-Chi HSIAO, Taoyuan City (TW); Chi-Ming YANG, Taoyuan City (TW)

(21) Appl. No.: 19/208,331

(22) Filed: May 14, 2025

(30) Foreign Application Priority Data
Jan. 10, 2025 (TW) 114101068

(51) Int. Cl. C25D 11/32; C23C 8/20; C23C 8/80; C30B 25/18; C30B 29/06; C30B 33/00

(52) U.S. Cl. CPC C25D 11/32; C23C 8/20; C23C 8/80; C30B 25/186; C30B 29/06; C30B 33/00

(57) ABSTRACT

A method for preparing an epitaxial structure includes: subjecting a single crystal silicon substrate to a carburizing treatment at a temperature ranging from 600°C to 1200°C, so as to obtain an intermediate structure including the single crystal silicon substrate and a 3C-SiC layer formed on the single crystal silicon substrate; placing the intermediate structure in a molten electrolyte of an electrolysis apparatus to permit the intermediate structure to serve as an anode, and applying a predetermined voltage to cause silicon atoms in the 3C-SiC layer to undergo electrolytic dissociation, such that the silicon atoms move out from lattice positions in the 3C-SiC layer and carbon atoms remaining in the lattice positions are rearranged to form a graphene layer; and growing an epitaxial film made of a group III-V semiconductor compound or a group II-VI semiconductor compound on the graphene layer. The epitaxial structure prepared by the method is also provided.

### CROSS-REFERENCE TO RELATED APPLICATION

This application claims priority to Taiwanese Invention Patent Application No. 114101068, filed on January 10, 2025, the entire disclosure of which is incorporated by reference herein.

### FIELD

The present disclosure relates to a method for preparing an epitaxial structure. The present disclosure also relates to an epitaxial structure prepared by the method.

### BACKGROUND

As a third-generation semiconductor material, gallium nitride (abbreviated as “GaN” hereinafter) has huge advantages with respect to high-frequency and high-voltage electronic components due to inherent material properties thereof. Manufacturers of electronic components are well aware that single crystal GaN must be grown by epitaxial techniques. Those familiar with epitaxy technology are also well aware that single crystal GaN is typically grown by heterogeneous epitaxy. That is, single crystal GaN is usually epitaxially grown on a single crystal substrate made of a material different from GaN, e.g., a single crystal sapphire (i.e., Al₂O₃) substrate, a single crystal silicon (Si) substrate, or a single crystal silicon carbide (SiC) substrate. However, it is well known that issues such as lattice mismatch, differences in the coefficient of thermal expansion (CTE) between GaN and Al₂O₃, Si, or SiC, etc., may occur. These issues may cause residual stress to be formed inside a GaN epitaxial layer grown on the single crystal sapphire substrate, the single crystal Si substrate, or the single crystal SiC substrate, resulting in crystal defects during subsequent manufacturing processes, which are undesirable in the industry. Therefore, the density of crystalline defect in the epitaxial films obtained by heterogeneous epitaxy is higher compared with that in the epitaxial films obtained by homogeneous epitaxy, and such crystalline defect affects the lifespan, performance, and production yield of electronic components. In contrast, graphene is a two-dimensional material with a surface thereof only having horizontal bonds and almost no vertical dangling bonds. Thus, when GaN is epitaxially grown on the surface of a graphene layer, the resultant GaN epitaxial layer and the graphene layer are connected by van der Waals force, allowing epitaxial growth to be completed without forming strong bonds (i.e., covalent bond or ionic bond). The aforesaid process results in a high-quality GaN epitaxial layer without residual stress, and the epitaxial technique used to grow such GaN epitaxial layer is referred to as van der Waals epitaxy in the industry.

Chinese Invention Patent Application Publication CN 113871473 A (referred to as “prior art document 1” hereinafter) discloses a conventional method for manufacturing a van der Waals epitaxial substrate and the van der Waals epitaxy used therein. The method disclosed in prior art document 1 includes the following procedures. First, a commercially available GaN is prepared to serve as a self-supporting GaN substrate. Next, a copper foil is used as a substrate for graphene growth, and hydrogen (H₂) and argon (Ar) gases are introduced into a quartz tube by chemical vapor deposition (CVD) after removal of residual gas therein, and the temperature is raised to 1000°C within 50 minutes, so as to allow the copper foil to be annealed at 1000°C for 30 minutes. Afterwards, 1 sccm of methane (CH₄) is introduced into the quartz tube and maintained for 10 minutes so as to form a plurality of nucleation sites on the annealed copper foil. Thereafter, 3 sccm of CH₄ is introduced into the quartz tube and maintained for 40 minutes so as to allow growth of a graphene monolayer on the nucleation sites. Finally, a roll-to-roll transfer method is employed to transfer the graphene monolayer onto the self-supporting GaN substrate, such that the graphene monolayer and the self-supporting GaN substrate together form a GaN-graphene substrate, thereby obtaining a conventional van der Waals epitaxial substrate. Prior art document 1 also discloses use of the conventional van der Waals epitaxial substrate in implementation of the van der Waals epitaxy, in which a two-dimensional van der Waals GaN single crystal thin film is epitaxially grown on the GaN-graphene substrate.

Although the epitaxial growth of the two-dimensional van der Waals GaN single crystal thin film can occur on the conventional van der Waals epitaxial substrate (i.e., the GaN-graphene substrate), the conventional method disclosed by prior art document 1 still requires use of the roll-to-roll transfer method to transfer the graphene monolayer from the copper foil onto the self-supporting GaN substrate. Those familiar with the roll-to-roll transfer method would know that the integrity of the graphene monolayer, after being transferred using such method, would be difficult to be maintained. During the roll-to-roll transfer, the graphene monolayer is prone to fractures and damages, resulting in the thus transferred graphene monolayer being adversely affected during subsequent implementation of the van der Waals epitaxy.

In view of the aforesaid, those skilled in the art endeavor to improve the method for producing van der Waals epitaxial film so as to maintain the integrity of the graphene layer on the van der Waals epitaxial substrate, and to address the issues associated with heterogeneous epitaxy.

### SUMMARY

Therefore, an object of the present disclosure is to provide a method for preparing an epitaxial structure and an epitaxial structure prepared thereby that can alleviate at least one of the drawbacks of the prior art.

According to an aspect of the present disclosure, the method for preparing an epitaxial structure includes the steps of:

(a) subjecting a single crystal silicon substrate to a carburizing treatment at a carburizing temperature ranging from 600°C to 1200°C, so as to obtain an intermediate structure including the single crystal silicon substrate and a 3C-SiC layer that is formed on a surface of the single crystal silicon substrate;

(b) placing the intermediate structure in a molten electrolyte of an electrolysis apparatus to permit the intermediate structure to serve as an anode, and applying a predetermined voltage to the anode to cause silicon atoms in the 3C-SiC layer to undergo electrolytic dissociation, such that the silicon atoms move out from lattice positions in the 3C-SiC layer and such that carbon atoms remaining in the lattice positions are rearranged to form a graphene layer; and

(c) growing an epitaxial film on the graphene layer, the epitaxial film being made of a group III-V semiconductor compound or a group II-VI semiconductor compound.

According to another aspect of the present disclosure, the epitaxial structure includes a single crystal silicon substrate, a graphene layer covering a surface of the single crystal silicon substrate, and an epitaxial film grown on the graphene layer. The epitaxial film is made of a group III-V semiconductor compound or a group II-VI semiconductor compound.

### BRIEF DESCRIPTION OF THE DRAWINGS

Other features and advantages of the present disclosure will become apparent in the following detailed description of the embodiment(s) with reference to the accompanying drawings. It is noted that various features may not be drawn to scale.

FIG. 1 is a schematic view illustrating implementation of step (a) of a method for preparing an epitaxial structure according to a first embodiment of the present disclosure.

FIG. 2 is a schematic view illustrating implementation of step (b) of the method for preparing an epitaxial structure according to the first embodiment of the present disclosure.

FIG. 3 is a schematic view illustrating an epitaxial structure obtained after implementation of step (c) of the method for preparing an epitaxial structure according to the first embodiment of the present disclosure.

FIG. 4 is a schematic view illustrating implementation of step (a) of the method for preparing an epitaxial structure according to a second embodiment of the present disclosure.

### DETAILED DESCRIPTION

Before the present disclosure is described in greater detail, it should be noted that where considered appropriate, reference numerals or terminal portions of reference numerals have been repeated among the figures to indicate corresponding or analogous elements, which may optionally have similar characteristics.

It should be noted herein that for clarity of description, spatially relative terms such as “top,” “bottom,” “upper,” “lower,” “on,” “above,” “over,” “downwardly,” “upwardly” and the like may be used throughout the disclosure while making reference to the features as illustrated in the drawings. The features may be oriented differently (e.g., rotated 90 degrees or at other orientations) and the spatially relative terms used herein may be interpreted accordingly.

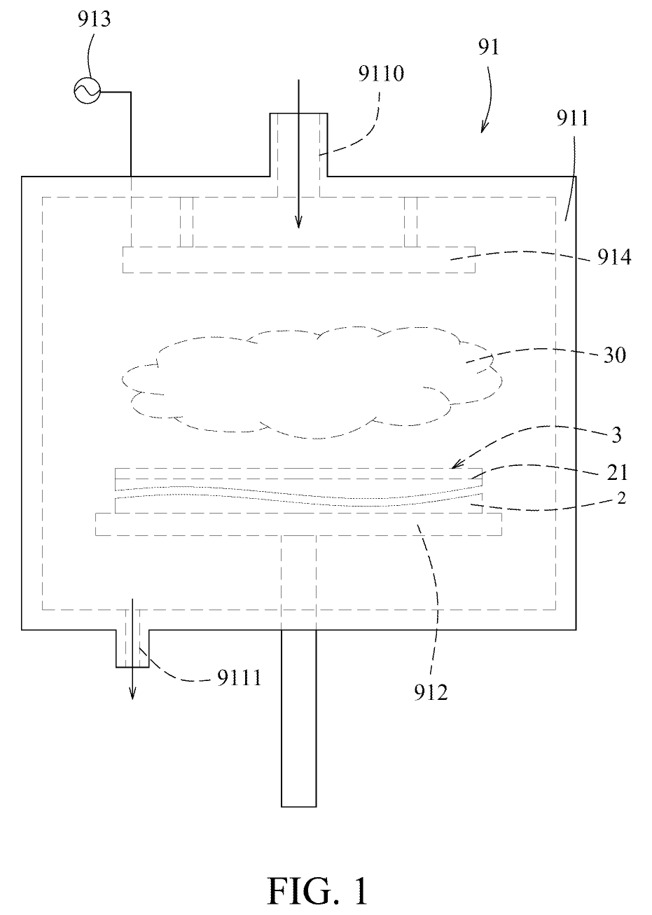

Referring to FIGS. 1 to 3, the present disclosure provides a method for preparing an epitaxial structure according to a first embodiment, and an epitaxial structure prepared thereby. The method for preparing an epitaxial structure of the first embodiment includes steps (a) to (c).

As shown in FIG. 1, in step (a), a single crystal silicon substrate 2 is subjected to a carburizing treatment at a carburizing temperature ranging from 600°C to 1200°C, so as to obtain an intermediate structure including the single crystal silicon substrate 2 and a 3C-SiC layer 3 that is formed on a surface 21 of the single crystal silicon substrate 2. In this embodiment, examples of the single crystal silicon substrate 2 may include, but are not limited to, an 8-inch silicon wafer and a 12-inch silicon wafer. It should be noted that, the 3C-SiC of the 3C-SiC layer 3 is known as β-phase silicon carbide in the semiconductor industry, and has a zinc blende (cubic) crystal structure.

In step (a) of the method of the first embodiment, the single crystal silicon substrate 2 is placed in a vacuum chamber 911 and a radio frequency voltage is applied across the vacuum chamber 911 to decompose a carbon source 30 in the vacuum chamber 911, such that the decomposed carbon source 30 diffuses to the surface 21 of the single crystal silicon substrate 2 during the carburization treatment performed at the carburizing temperature. Therefore, in step (a) of the method of the first embodiment, carbon ions of the decomposed carbon source 30, which diffuse to the surface 21 of the single crystal silicon substrate 2, can chemically react with the silicon on the surface 21, so as to form the 3C-SiC layer 3 on the surface 21 of the single crystal silicon substrate 2.

To be specific, in step (a) of the method of the first embodiment, the single crystal silicon substrate 2 is placed on a carrier 912 in the vacuum chamber 911 of a plasma-enhanced chemical vapor deposition (abbreviated as PECVD hereinafter) system 91, in which the carrier 912 serves as a first electrode of the PECVD system 91. The single crystal silicon substrate 2 placed on the carrier 912 is then heated to the carburizing temperature by a heater (not shown) that is connected to the carrier 912 through a signal, and the carbon source 30 is introduced from a gas inlet 9110 of the vacuum chamber 911. Next, the radio frequency voltage is applied from a radio frequency power supply 913 of the PECVD system 91 to a second electrode 914 of the PECVD system 91 so as to decompose the carbon source 30. In this case, a bias voltage ranging from -50 V and -500 V is applied to the carrier 912, so that the decomposed carbon source 30 diffuses to the surface 21 of the single crystal silicon substrate 2 at the carburizing temperature to chemically react with the silicon on the surface 21. The resultant residual gas is then extracted through a gas outlet 9111 of the vacuum chamber 911, so that a working pressure ranging from 0.1 Pa and 50.0 Pa is maintained in the vacuum chamber 911. The carbon source 30 suitable for use in step (a) of the method according to the present disclosure may include a hydrocarbon gas selected from the group consisting of methane (CH₄), ethylene (C₂H₄), acetylene (C₂H₂), and combinations thereof. In step (a) of the method of the first embodiment, the radio frequency applied from the radio frequency power supply 913 ranges from 10 MHz to 50 MHz, and the carburizing treatment is performed for a first predetermined time period of not greater than 2 hours, such that the 3C-SiC layer 3 formed on the surface 21 of the single crystal silicon substrate 2 has a first thickness ranging from 0.4 nm to 20.0 nm.

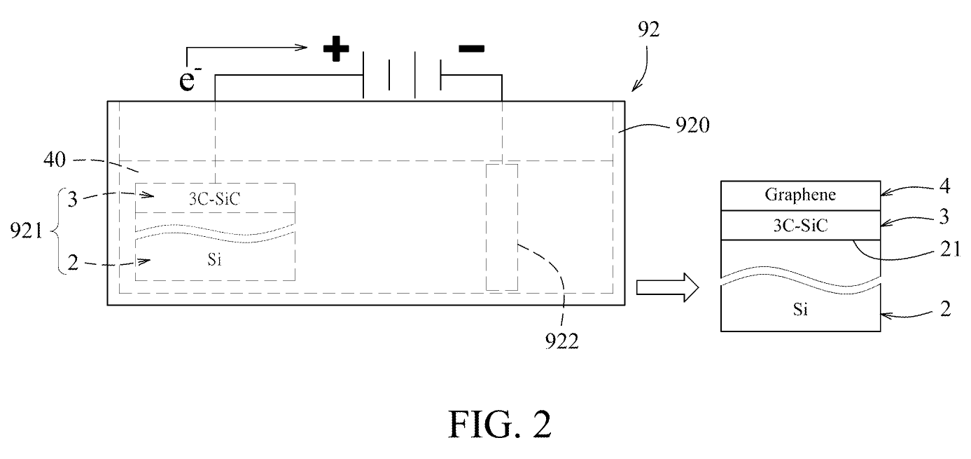

As shown in FIG. 2, the intermediate structure, which includes the single crystal silicon substrate 2 and the 3C-SiC layer 3, is placed in a molten electrolyte 40 of an electrolysis apparatus 92 to permit the intermediate structure to serve as an anode 921 of the electrolysis apparatus 92, and then a predetermined voltage is applied to the anode 921 to cause silicon atoms in the 3C-SiC layer 3 to undergo electrolytic dissociation, such that the silicon atoms move out from lattice positions in the 3C-SiC layer 3, and such that carbon atoms remaining in the lattice positions of the 3C-SiC layer 3 are rearranged to form a graphene layer 4. Therefore, in the method of the first embodiment, the graphene layer 4 is obtained by subjecting the silicon atoms in the 3C-SiC layer 3 to electrolytic dissociation on the surface 21 of the single crystal silicon substrate 2, and by rearrangement of the carbon atoms remaining in the lattice positions of the 3C-SiC layer 3. In some embodiments, after step (b), the remaining 3C-SiC layer 3 is located beneath the graphene layer 4, as shown in FIG. 2.

To be specific, in step (b) of the method of the first embodiment, the intermediate structure, which includes the single crystal silicon substrate 2 and the 3C-SiC layer 3, is placed in the molten electrolyte 40 in a reaction tank 920 of the electrolysis apparatus 92 to permit the intermediate structure to serve as the anode 921 of the electrolysis apparatus 92, and a graphite rod is placed in the molten electrolyte 40 to serve as a cathode 922 of the electrolysis apparatus 92. Next, the predetermined voltage is applied to the anode 921 and the cathode 922, causing silicon atoms in the 3C-SiC layer 3 to undergo electrolytic dissociation, such that the silicon atoms move out from lattice positions in the 3C-SiC layer 3, and such that carbon atoms remaining in the lattice positions of the 3C-SiC layer 3 are rearranged to form the graphene layer 4. In step (b) of the method of the first embodiment, the predetermined voltage ranges from 1 V to 10 V, and is applied for a second predetermined time period of not greater than 1 hour, such that the graphene layer 4 thus obtained has a second thickness ranging from 0.3 nm to 20.0 nm.

It should be noted that, in step (b), rearrangement of the carbon atoms to form the graphene layer 4 still relies on the driving force of temperature. Therefore, in step (b) of the method of the first embodiment, the molten electrolyte 40 is prepared from an inorganic salt that has a melting temperature of not lower than 600°C and not greater than 1400°C. The inorganic salt suitable for use in the method according to present disclosure may include an inorganic chloride compound selected from a group IA inorganic chloride compound and a group IIA inorganic chloride compound. Examples of the inorganic chloride compound may include, calcium chloride (CaCl₂), potassium chloride (KCl), and lithium chloride (LiCl). In the first embodiment, the inorganic chloride compound is CaCl₂, and in step (b), the temperature of the reaction tank 920 is elevated to be not lower than 772°C (i.e., the melting temperature of CaCl₂), such that CaCl₂ in solid form is melted into liquid form, and the carbon atoms are rearranged to form the graphene layer 4 at the temperature of approximately 772°C.

In step (c) of the method of the first embodiment, an epitaxial film 5 is grown on the graphene layer 4. The epitaxial film 5 is made of a group III-V semiconductor compound or a group II-VI semiconductor compound. In the first embodiment, the group III-V semiconductor compound may be selected from the group consisting of gallium nitride (GaN), aluminum nitride (AlN), gallium arsenide (GaAs), and aluminum indium gallium nitride (AlInGaN). In the first embodiment, the group II-VI semiconductor compound may be selected from the group consisting of zinc sulfide (ZnS), zinc selenide (ZnSe), lead sulfide (PbS), and zinc oxide (ZnO). In an example of the method of first embodiment, the epitaxial film 5 is made of a GaN-based semiconductor material, i.e., group III-V semiconductor compound, but is not limited thereto. In step (c) of the method of the first embodiment, the epitaxial film 5 is grown at an epitaxial temperature that is lower than 1400°C.

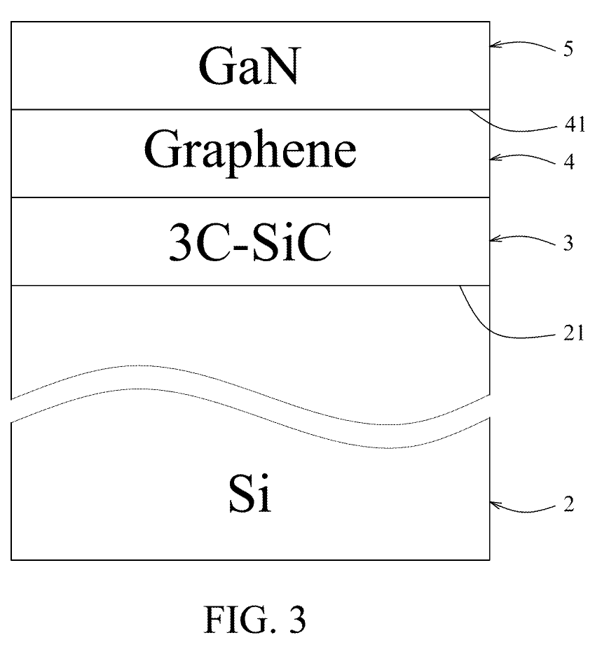

From the description above, in the method of the first embodiment according to the present disclosure, a silicon wafer having a relatively large surface area (8-inch or 12-inch) is utilized as the single crystal silicon substrate 2, and the 3C-SiC layer 3 is first formed on the surface 21 of the single crystal silicon substrate 2 in step (a), followed by rearrangement of the carbon atoms remaining in the lattice positions of the 3C-SiC layer 3 so as to form the graphene layer 4 in step (b). Therefore, a surface area of the graphene layer 4 obtained in step (b) is same as or substantially the same as a surface area of the surface 21 of the single crystal silicon substrate 2, and a surface area of the epitaxial film 5 is same as or substantially the same as the surface area of the surface 21 of the single crystal silicon substrate 2. In addition, as shown in FIG. 3, an epitaxial structure prepared by the method of the first embodiment according to the present disclosure includes the single crystal silicon substrate 2, the graphene layer 4 covering the surface 21 of the single crystal silicon substrate 2, the epitaxial film 5 grown on the graphene layer 4, and the 3C-SiC layer 3 that is formed on the surface 21 of the single crystal silicon substrate 2 and that is sandwiched between the single crystal silicon substrate 2 and the graphene layer 4. It is worth mentioning that, the graphene layer 4 is formed by rearrangement of the carbon atoms remaining on the surface of the 3C-SiC layer 3, and thus the problem of graphene damage caused by the roll-to-roll transfer method will not occur, thereby being advantageous for van der Waals epitaxy to be conducted on a relatively large surface area. In addition, the graphene layer 4 is a two-dimensional material, and surface thereof have no dangling bonds, which is conducive to the epitaxial growth of the epitaxial film 5 that is free of stress and made of the GaN-based group III-V semiconductor compound. Therefore, the method of the first embodiment also solves the problems incurred by heterogeneous epitaxy. It is also worth to note that, a van der Waals epitaxial interface 41 exists between the graphene layer 4 and the epitaxial film 5. Since the graphene layer 4 and the epitaxial film 5 are merely connected by van der Waals forces therebetween, an atomic bonding strength in the epitaxial film 5 is relatively lower than a covalent bonding strength of an epitaxial layer obtained by heterogeneous epitaxy. Therefore, the atoms in the epitaxial film 5 may be free from being bonded strongly in the horizontal direction, thereby alleviating the residual stress caused by lattice constant mismatch and large difference in the coefficient of thermal expansion (CTE) during epitaxial growth. As can be known from the foregoing, the method of the first embodiment according to the present disclosure allows the preparation of the epitaxial structure having a relatively large surface area and being free of residual stress. Thus, such epitaxial structure has a low defect density and is suitable to be applied in, for example, horizontal power semiconductor electronic components, etc.

The epitaxial structure obtained by the method of the first embodiment according to the present disclosure includes, for example, the single crystal silicon substrate 2, the 3C-SiC layer 3, the graphene layer 4, and the epitaxial film 5. It should be noted that, in certain embodiments, when the 3C-SiC layer 3 is relatively thin, and the time period for implementing step (b) is sufficient to fully remove the silicon atoms in the 3C-SiC layer 3, only the carbon atoms remain in the lattice positions of the 3C-SiC layer 3. As such, the epitaxial structure, which is obtained after the carbon atoms remaining in the lattice positions of the 3C-SiC layer 3 are rearranged to form the graphene layer 4, only includes the single crystal silicon substrate 2, the graphene layer 4 covering the surface 21 of the single crystal silicon substrate 2, and the epitaxial film 5 epitaxially grown on the graphene layer 4.

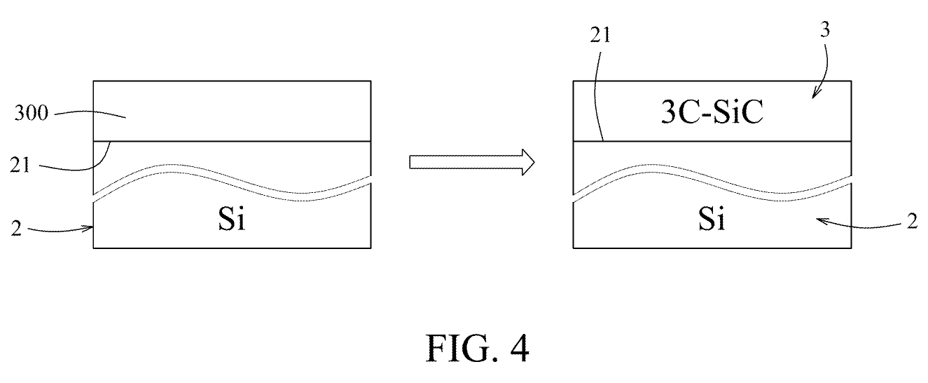

Referring to FIG. 4, a second embodiment of the method for preparing an epitaxial structure according to the present disclosure and the epitaxial structure prepared thereby are substantially similar to those of the first embodiment, except that in step (a) of the method of the second embodiment, the single crystal silicon substrate 2 is placed in a vertical tube reactor (not shown in the figures) and a precursor component containing an iron source, a sulfur source and the carbon source 30 is introduced into the vertical tube reactor, such that during introduction of the precursor component into the vertical tube reactor, the carbon source 30 of the precursor component decomposes and is deposited on the surface 21 of the single crystal silicon substrate 2 to form a carbon ion layer 300, resulting in carbon ions in the carbon ion layer 300 diffusing to the surface 21 of the single crystal silicon substrate 2 during the carburization treatment performed at the carburizing temperature. It should be noted that, the iron source of the precursor component provides a catalytic effect to the carbon source 30 to facilitate decomposition of the carbon source 30 so that the carbon atoms therein form carbon ions at an appropriate temperature, and the sulfur source of the precursor component is capable of assisting the catalytic effect of the iron source so as to enhance the decomposition of the carbon source 30. To be specific, the iron source, the sulfur source and the carbon source of the precursor component are respectively introduced into the vertical tube reactor through pipelines of different lengths, and temperature gradient in the vertical tube reactor is adjusted to allow the iron source and the sulfur source to effectively decompose the carbon source 30, such that the surface 21 of the single crystal silicon substrate 2 is covered with the carbon ions to form the carbon ion layer 300. As a result, the carbon ions diffusing to the surface 21 of the single crystal silicon substrate 2 at the carburizing temperature form the 3C-SiC layer 3. Thereafter, RCA cleaning and drying are conducted in sequence. In step (a) of the method of the second embodiment, the iron source may be selected from the group consisting of ferrocene [Fe(C₅H₅)₂], iron (Fe), and ferrous chloride (FeCl₂). In step (a) of the method of the second embodiment, the sulfur source may be selected from the group consisting of sulfur and thiophene (C₄H₄S).

In summary, in the method for preparing an epitaxial structure according to the present disclosure, by virtue of implementing step (a), in which the 3C-SiC layer 3 is directly formed on the surface 21 of the single crystal silicon substrate 2 which has a relatively large surface area, and then implementing step (b), in which electrolytic dissociation occurs such that the carbon atoms remaining on the surface of the 3C-SiC layer 3 are rearranged to form the graphene layer 4 that is intact and that has a surface area the same as or substantially the same as that of the surface 21 of the single crystal silicon substrate 2, the van der Waals force in the surface of the graphene layer 4 is more conducive to the epitaxial growth of the epitaxial film 5 that is free of stress and made of the GaN-based group III-V semiconductor compound, and thus the problems incurred by heterogeneous epitaxy can be solved. Therefore, the purpose of the present disclosure can indeed be achieved.

In the description above, for the purposes of explanation, numerous specific details have been set forth in order to provide a thorough understanding of the embodiment(s). It will be apparent, however, to one skilled in the art, that one or more other embodiments may be practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects; such does not mean that every one of these features needs to be practiced with the presence of all the other features. In other words, in any described embodiment, when implementation of one or more features or specific details does not affect implementation of another one or more features or specific details, said one or more features may be singled out and practiced alone without said another one or more features or specific details. It should be further noted that one or more features or specific details from one embodiment may be practiced together with one or more features or specific details from another embodiment, where appropriate, in the practice of the disclosure.

While the disclosure has been described in connection with what is (are) considered the exemplary embodiment(s), it is understood that this disclosure is not limited to the disclosed embodiment(s) but is intended to cover various arrangements included within the spirit and scope of the broadest interpretation so as to encompass all such modifications and equivalent arrangements.

What is claimed is:

1. A method for preparing an epitaxial structure, comprising the steps of:
(a) subjecting a single crystal silicon substrate to a carburizing treatment at a carburizing temperature ranging from 600°C to 1200°C, so as to obtain an intermediate structure including the single crystal silicon substrate and a 3C-SiC layer that is formed on a surface of the single crystal silicon substrate;(b) placing the intermediate structure in a molten electrolyte of an electrolysis apparatus to permit the intermediate structure to serve as an anode, and applying a predetermined voltage to the anode to cause silicon atoms in the 3C-SiC layer to undergo electrolytic dissociation, such that the silicon atoms move out from lattice positions in the 3C-SiC layer and such that carbon atoms remaining in the lattice positions are rearranged to form a graphene layer; and(c) growing an epitaxial film on the graphene layer, the epitaxial film being made of a group III-V semiconductor compound or a group II-VI semiconductor compound.

2. The method as claimed in claim 1, wherein in step (a), the single crystal silicon substrate is placed in a vacuum chamber and a radio frequency voltage is applied across the vacuum chamber to decompose a carbon source in the vacuum chamber, such that the decomposed carbon source diffuses to the surface of the single crystal silicon substrate during the carburization treatment performed at the carburizing temperature.

3. The method as claimed in claim 1, wherein in step (a), the single crystal silicon substrate is placed in a vertical tube reactor and a precursor component containing an iron source, a sulfur source and a carbon source is introduced into the vertical tube reactor, such that during introduction of the precursor component into the vertical tube reactor, the carbon source of the precursor component decomposes and is deposited on the surface of the single crystal silicon substrate to form a carbon ion layer, carbon ions in the carbon ion layer diffusing to the surface of the single crystal silicon substrate during the carburization treatment performed at the carburizing temperature.

4. The method as claimed in claim 2, wherein in step (a), the carbon source includes a hydrocarbon gas selected from the group consisting of methane, ethylene, acetylene, and combinations thereof.

5. The method as claimed in claim 3, wherein in step (a), the carbon source includes a hydrocarbon gas selected from the group consisting of methane, ethylene, acetylene, and combinations thereof.

6. The method as claimed in claim 1, wherein in step (a), the carburizing treatment is performed for a first predetermined time period of not greater than 2 hours.

7. The method as claimed in claim 1, wherein in step (b), the predetermined voltage ranges from 1 V to 10 V, and is applied for a second predetermined time period of not greater than 1 hour.

8. The method as claimed in claim 1, wherein in step (b), the molten electrolyte is prepared from an inorganic chloride compound.

9. The method as claimed in claim 1, wherein in step (c), the epitaxial film is grown at an epitaxial temperature that is lower than 1400°C.

10. An epitaxial structure, comprising:
a single crystal silicon substrate;
a graphene layer covering a surface of the single crystal silicon substrate; and
an epitaxial film grown on the graphene layer, the epitaxial film being made of a group III-V semiconductor compound or a group II-VI semiconductor compound.

11. The epitaxial structure as claimed in claim 10, further comprising a 3C-SiC layer formed on the surface of the single crystal silicon substrate, the 3C-SiC layer being sandwiched between the single crystal silicon substrate and the graphene layer.

12. The epitaxial structure as claimed in claim 11, wherein the 3C-SiC layer has a first thickness ranging from 0.4 nm to 20.0 nm.

13. The epitaxial structure as claimed in claim 10, wherein the graphene layer has a second thickness ranging from 0.3 nm to 20.0 nm.

14. The epitaxial structure as claimed in claim 10, wherein a surface area of the epitaxial film is same as a surface area of the surface of the single crystal silicon substrate.
